(19) United States
(12) Patent Application Publication
(10) Pub. No.: US 2012/0056686 A1
(43) Pub. Date: Mar. 8, 2012

(54) VIBRATOR ELEMENT, VIBRATOR, VIBRATION DEVICE, AND ELECTRONIC DEVICE

(75) Inventor: Hiroki KAWAI, Chino (JP)

(73) Assignee: SEIKO EPSON CORPORATION, Tokyo (JP)

(21) Appl. No.: 13/225,994

(22) Filed: Sep. 6, 2011

(30) Foreign Application Priority Data
Sep. 8, 2010 (JP) 2010-200800

(51) Int. Cl. H01L 41/04; H03B 5/32

(52) U.S. Cl. 331/158; 310/370

(57) ABSTRACT

A vibrator element includes: a base portion; a plurality of vibrating arms which extends in the Y-axis direction from the base portion so as to be arranged in a line in the X-axis direction, and piezoelectric elements which are formed on the vibrating arms so as to allow the vibrating arms to perform flexural vibration in the Z-axis direction. The respective vibrating arms include first surfaces which are compressed or expanded in response to flexural vibration and second surfaces which are expanded when the first surfaces are compressed and which are compressed when the first surfaces are expanded. The vibrating arms have the piezoelectric elements which are formed close to the first surfaces, and the other vibrating arm has the piezoelectric element which is formed close to the second surface.

### BACKGROUND

1. Technical Field

The present invention relates to a vibrator element, a vibrator, a vibration device, and an electronic device.

2. Related Art

As a vibration device such as a quartz crystal oscillator, a vibration device which includes a tuning fork-type vibrator element that includes a plurality of vibrating arms is disclosed in JP-A-2009-005022, for example.

For example, the vibrator element disclosed in JP-A-2009-005022 includes a base portion, three vibrating arms extending in parallel to each other from the base portion, and a piezoelectric element in which a lower electrode film, a piezoelectric film, and an upper electrode film are formed in that order on the respective vibrating arms. In such a vibrator element, when an electric field is applied between the lower electrode film and the upper electrode film, a piezoelectric layer of the piezoelectric element is expanded and compressed, whereby the vibrating arms perform flexural vibration in the thickness direction (a so-called out of-plane direction) of the base portion. In this case, two adjacent vibrating arms perform flexural vibration in opposite directions to each other. That is, when the two vibrating arms (outer vibrating arms) positioned at both ends perform flexural vibration toward one side in the thickness direction, one vibrating arm (central vibrating arm) positioned at the center performs flexural vibration toward the other side in the thickness direction. On the other hand, when the two outer vibrating arms perform flexural vibration toward the other side in the thickness direction, the central vibrating arm performs flexural vibration toward one side in the thickness direction. In this way, vibration leakage is suppressed, and vibration characteristics are improved.

However, such a vibrator element disclosed in JP-A-2009-005022 has the following problem since the piezoelectric element is formed on the same surfaces (upper surfaces) of the three vibrating arms. That is, wirings (hereinafter first wirings) which connect the upper electrode films of the two outer vibrating arms and the lower electrode film of the central vibrating arm cross wirings (hereinafter second wirings) which connect the lower electrode films of the two outer vibrating arms and the upper electrode film of the central vibrating arm, which makes the wirings very complicated. In this case, in the crossing portions of the first and second wirings, it is necessary to form an insulating film between the first and second wirings so as to electrically isolate both wirings, which may deteriorate manufacturing efficiency.

Moreover, the vibrator element disclosed in JP-A-2009-005022 has the following problem since the piezoelectric element is formed on the same surfaces (upper surfaces) of the three vibrating arms. That is, although the centers of the respective vibrating arms are positioned approximately at the center in the thickness direction thereof, since the piezoelectric element is formed on the same surfaces (upper surfaces) of the three vibrating arms, the centers of the respective vibrating arms are shifted toward the upper side (a surface side where the piezoelectric element is formed). When the centers of all the vibrating arms are shifted in the same direction, balance in the flexural vibration of the three vibrating arms collapses, and vibration characteristics deteriorate.

### SUMMARY

An advantage of some aspects of the invention is to provide a vibrator element which is at least capable of simplifying wirings and improving vibration characteristics through an improvement in vibration balance. Another advantage of some aspects of the invention is to provide a vibrator, a vibration device, and an electronic device which each have the vibrator element and have excellent reliability.

### Application Example 1

This application example of the invention is directed to a vibrator element including: a base portion formed on a plane including a first direction and a second direction orthogonal to the first direction; a plurality of vibrating arms which extends in the first direction from the base portion and are arranged in a line in the second direction; and a piezoelectric element which is formed in each of the vibrating arms so as to cause the vibrating arm to perform flexural vibration in a normal direction to the plane, wherein each of the vibrating arms includes a first surface which is compressed or expanded in response to the flexural vibration, a second surface which is expanded when the first surface is compressed and which is compressed when the first surface is expanded, and a side surface that connects the first and second surfaces, wherein a plurality of the vibrating arms includes a first vibrating arm and a second vibrating arm which perform the flexural vibration in the opposite directions to each other, wherein the first vibrating arm has the piezoelectric element which is formed close to the first surface, and wherein the second vibrating arm has the piezoelectric element which is formed close to the second surface.

With this configuration, it is possible to obviate wirings from crossing each other as compared to when all piezoelectric elements are disposed on the sides of one surface of the vibrating arms as in the related art. Moreover, it is possible to suppress a shift of the centers of all of the plurality of vibrating arms in a direction normal to a plane including the first and second directions. Therefore, the respective vibrating arms can perform flexural vibration in the normal direction in a well-balanced manner. As a result, it is possible to obtain a vibrator element capable of exhibiting excellent vibration characteristics.

### Application Example 2

In the vibrator element of the application example of the invention, it is preferable that the first vibrating arm and the second vibrating arm be alternately arranged in the second direction.

With this configuration, it is possible to cancel leakage vibration generated by two adjacent vibrating arms. As a result, it is possible to prevent vibration leakage.

### Application Example 3

In the vibrator element of the application example of the invention, it is preferable that each of the piezoelectric elements include a first electrode layer, a second electrode layer, and a piezoelectric layer disposed between the first and second electrode layers, the first vibrating arm disposes the first electrode layer which is formed on the first surface, and the second vibrating arm disposes the first electrode layer which is formed on the second surface.

With this configuration, it is possible to connect the first electrode layers of the respective piezoelectric elements without any step. Thus, the reliability of the vibrator element is improved. Moreover, even when the directions of the polarization axes or the crystal axes of the vibrating arms are not ideal for the flexural vibration, it is possible to allow the respective vibrating arms to perform flexural vibration in a relatively simple and effective manner, regardless of whether the vibrating arms themselves have piezoelectric properties or not. Moreover, since the presence of the piezoelectric properties and the directions of the polarization axes or the crystal axes of the vibrating arms do not make any significant difference, the range of choices for the material of the respective vibrating arms widens. Thus, it is possible to realize the vibrator element having desired vibration characteristics relatively easily.

### Application Example 4

In the vibrator element of the application example of the invention, it is preferable that the second electrode layer which is formed in at least one of the first and second vibrating arms be extracted to a surface on the opposite side to a surface where the first electrode layer is formed through the side surface of the vibrating arm.

With this configuration, electrical extraction of the second electrode layer to the base portion can be performed in a simple manner.

### Application Example 5

In the vibrator element of the application example of the invention, it is preferable that a first connection electrode and a second connection electrode be formed on the base portion, the first connection electrode be connected to each of the first electrode layers formed on the plurality of the vibrating arms, and the second connection electrodes be connected to each of the second electrode layers formed on the plurality of the vibrating arms.

With this configuration, it is possible to extract the first and second electrode layers to the base portion.

### Application Example 6

In the vibrator element of the application example of the invention, it is preferable that the piezoelectric layer be formed at least up to a formation region of the second connection electrode and overlaps with the second connection electrode in a plan view thereof.

With this configuration, a portion of the first electrode layer extracted to the base portion and a portion of the second electrode layer extracted to the base portion can be electrically isolated by the piezoelectric layer.

### Application Example 7

This application example of the invention is directed to a vibrator including: the vibrator element of the above application example; and a package in which the vibrator element is accommodated.

With this configuration, it is possible to provide a vibrator having excellent reliability.

### Application Example 8

This application example of the invention is directed to a vibration device including: the vibrator element of the above application example; and an oscillation circuit connected to the vibrator element.

With this configuration, it is possible to provide a vibration device, such as an oscillator, having excellent reliability.

### Application Example 9

This application example of the invention is directed to an electronic device including the vibrator element of the above application example.

With this configuration, it is possible to provide an electronic device, such as a cellular phone, a personal computer, or a digital camera, having excellent reliability.

### BRIEF DESCRIPTION OF THE DRAWINGS

The invention will be described with reference to the accompanying drawings, wherein like numbers reference like elements.

FIG. 1 is a cross-sectional view showing a vibrator according to a first embodiment of the invention.

FIG. 2 is a top view showing the vibrator shown in FIG. 1.

FIG. 3 is a bottom view showing the vibrator shown in FIG. 1.

FIG. 4 is a cross-sectional view taken along the line A-A in FIG. 2.

FIG. 5 is a top view showing the vibrator shown in FIG. 1.

FIG. 6 is a perspective view illustrating the operation of the vibrator element shown in FIG. 2.

FIGS. 7A and 7B are cross-sectional views illustrating advantageous effects over a vibrator element of the related art.

FIG. 8 is a cross-sectional view illustrating a vibrator element according to a second embodiment of the invention.

FIG. 9 is a cross-sectional view illustrating a vibrator element according to a third embodiment of the invention.

FIG. 10 shows an electronic device (notebook-type personal computer) including the vibrator element of an embodiment of the invention.

FIG. 11 shows an electronic device (cellular phone) including the vibrator element of an embodiment of the invention.

FIG. 12 shows an electronic device (digital still camera) including the vibrator element of an embodiment of the invention.

### DESCRIPTION OF EXEMPLARY EMBODIMENTS

Hereinafter, a vibrator element, a vibrator, a vibration device, and an electronic device of the invention will be described in detail based on embodiments illustrated in the accompanying drawings.

### First Embodiment

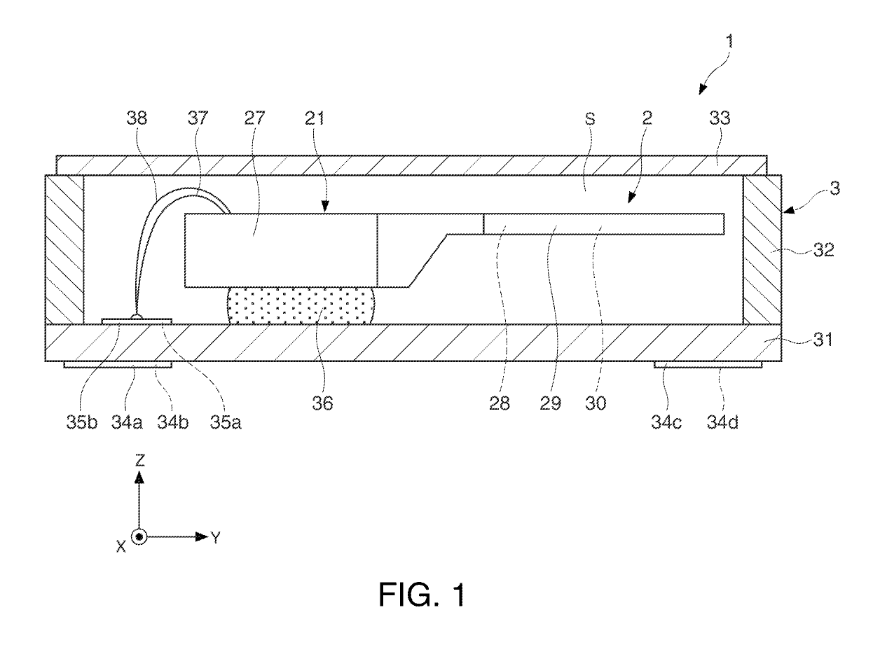

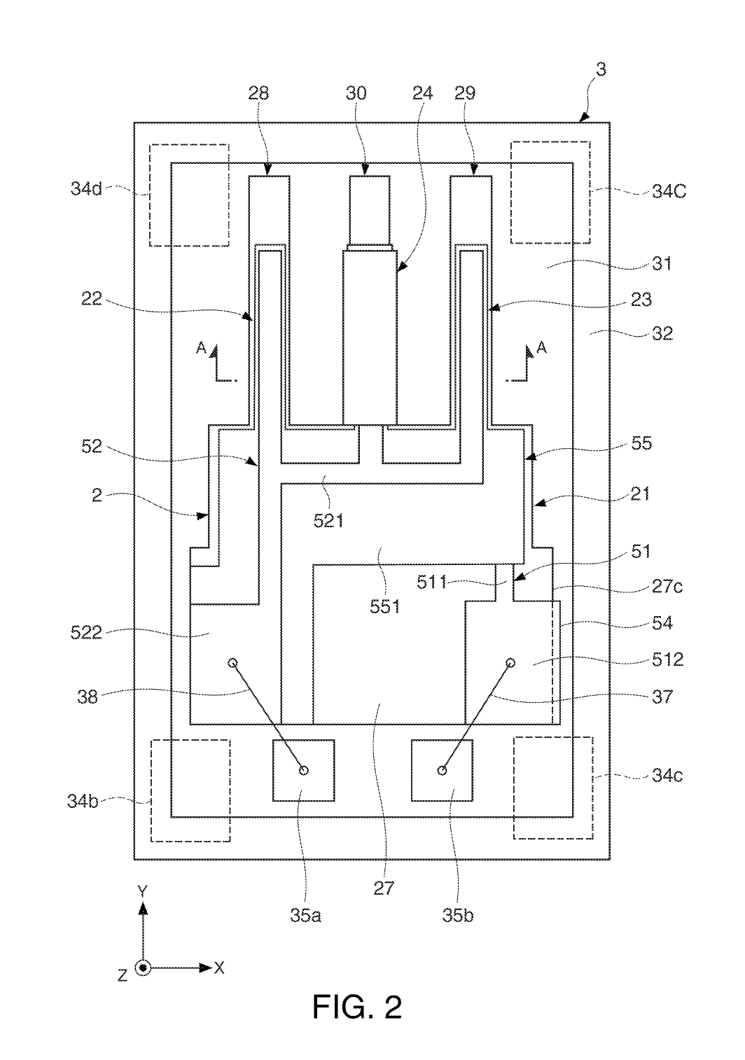

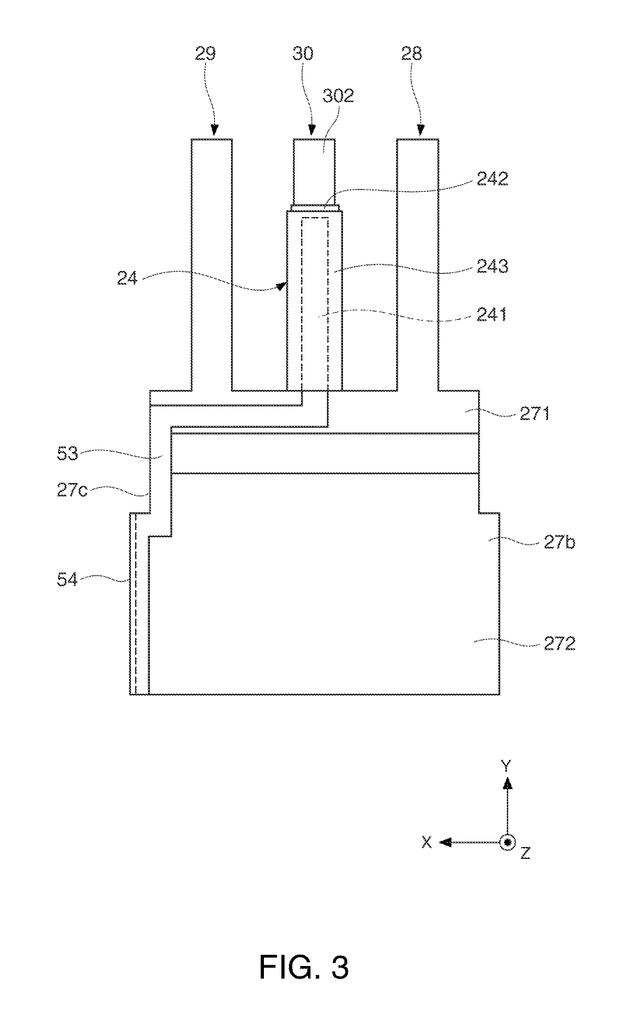

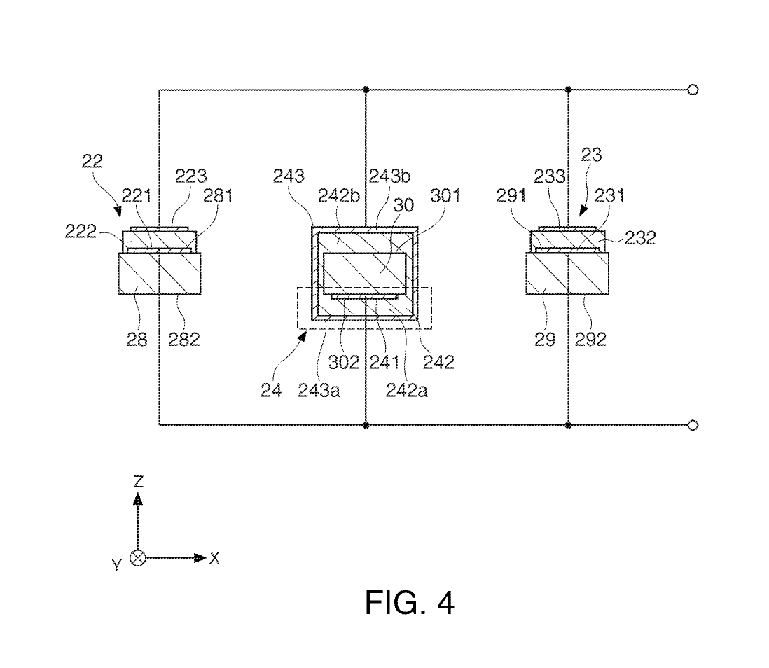

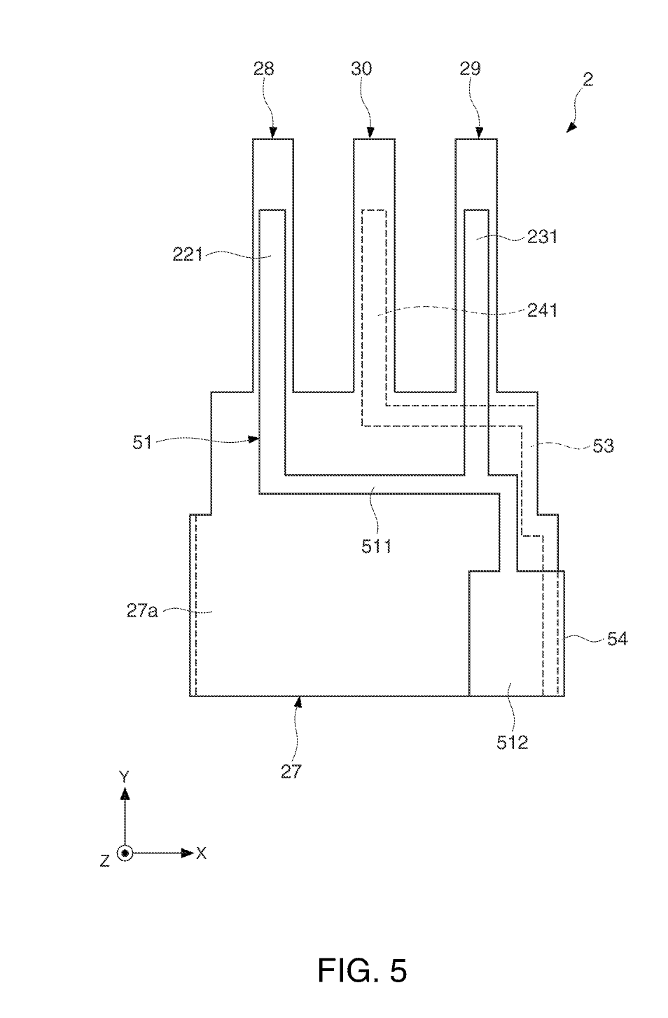

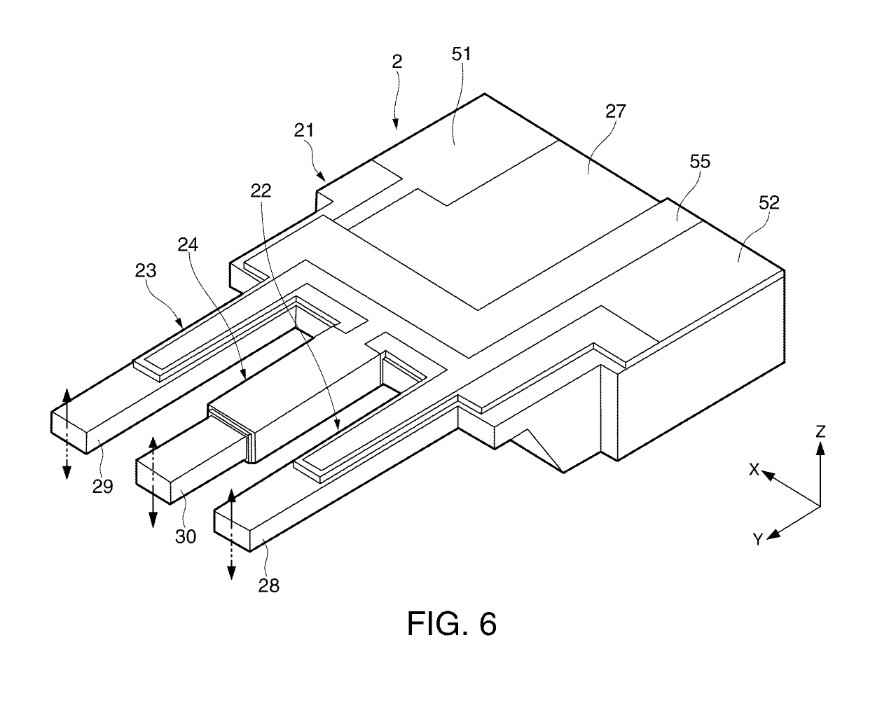

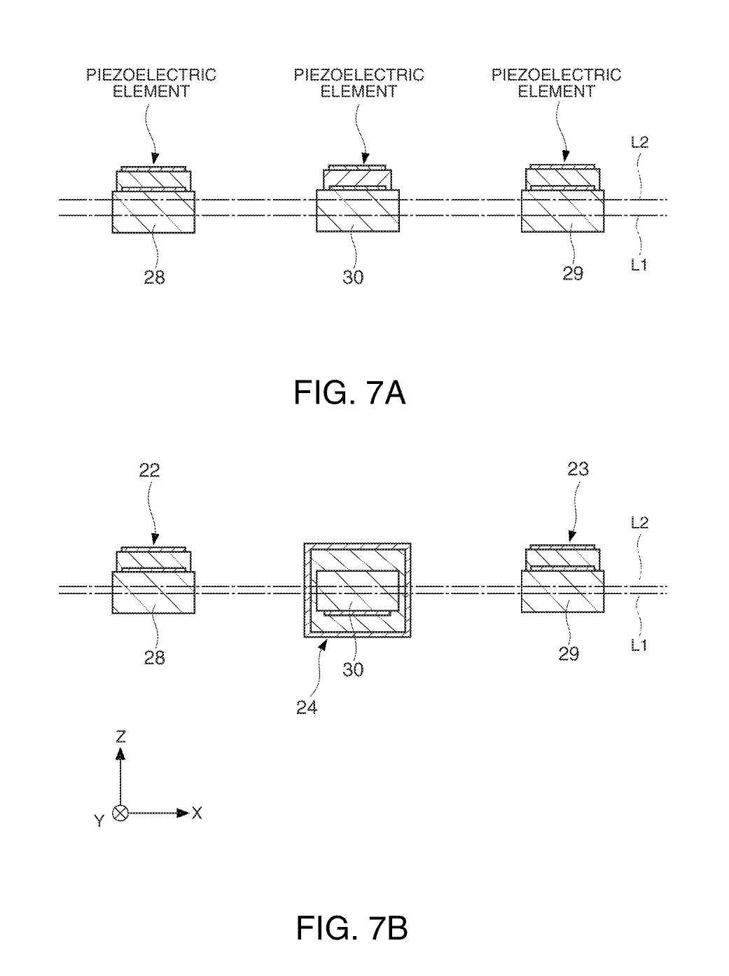

FIG. 1 is a cross-sectional view showing a vibrator according to a first embodiment of the invention; FIG. 2 is a top view showing the vibrator shown in FIG. 1; FIG. 3 is a bottom view showing the vibrator shown in FIG. 1; FIG. 4 is a cross-sectional view taken along the line A-A in FIG. 2; FIG. 5 is a top view showing the vibrator shown in FIG. 1; FIG. 6 is a perspective view illustrating the operation of the vibrator element shown in FIG. 2; and FIGS. 7A and 7B are cross-sectional views illustrating advantageous effects over a vibrator element of the related art.

In the respective drawings, for the sake of convenience, X, Y, and Z axes are illustrated as three orthogonal axes. In the following explanation, a direction (first direction) parallel to the Y axis will be referred to as a “Y-axis direction”, a direction (second direction) parallel to the X axis referred to as an “X-axis direction,” and a direction (normal direction of a plane including the first and second directions) parallel to the Z axis referred to as a “Z-axis direction”. Moreover, in the following explanation, for the sake of convenience, the upper side in FIG. 1 will be referred to as “top,” the lower side referred to as “bottom,” the right side referred to as “right,” and the left side referred to as “left”. Furthermore, in FIG. 1, for the sake of convenience, the illustrations of a plurality of piezoelectric elements and a plurality of wiring layers formed on a vibration substrate 21 are omitted.

A vibrator 1 shown in FIG. 1 includes a vibrator element 2 and a package 3 in which the vibrator element 2 is accommodated.

Hereinafter, respective parts constituting the vibrator 1 will be sequentially described in detail.

### Vibrator Element

First, the vibrator element 2 will be described.

The vibrator element 2 is a three-leg tuning fork-type vibrator element as shown in FIG. 2, for example. The vibrator element 2 includes a vibration substrate 21, and piezoelectric elements 22, 23, 24, first to fourth wiring layers 51 to 54, and an insulating layer 55 which are formed on the vibration substrate 21.

The vibration substrate 21 includes a base portion 27 and three vibrating arms 28, 29, and 30.

The material of the vibration substrate 21 is not particularly limited as long as it can exhibit desired vibration characteristics, and various piezoelectric materials and various non-piezoelectric materials can be used.

Examples of the piezoelectric material include quartz crystal, lithium tantalate, lithium niobate, lithium borate, barium titanate, and the like. In particular, quartz crystal (X-cut substrate, AT-cut substrate, Z-cut substrate, or the like) is preferred as a piezoelectric material that forms the vibration substrate 21. When the vibration substrate 21 is formed of a quartz crystal, it is possible to obtain the vibration substrate 21 having excellent vibration characteristics (particularly, frequency-temperature characteristics). Moreover, it is possible to form the vibration substrate 21 with high dimensional accuracy by etching.

Moreover, examples of the non-piezoelectric material include silicon, quartz, and the like. In particular, silicon is preferred as a non-piezoelectric material that forms the vibration substrate 21. When the vibration substrate 21 is formed of silicon, it is possible to realize the vibration substrate 21 having excellent vibration characteristics at a relatively low cost. Moreover, for example, when an integrated circuit is formed on the base portion 27, it is easy to integrate the vibrator element 2 with other circuit elements. Furthermore, it is possible to form the vibration substrate 21 with high dimensional accuracy by etching.

In such a vibration substrate 21, the base portion 27 has an approximately plate-like shape in which the thickness direction is the Z-axis direction. Moreover, as shown in FIGS. 1 and 3, the base portion 27 includes a thin portion 271 having a small thickness and a thick portion 272 having a larger thickness than the thin portion 271, and these portions are arranged in a line in the Y-axis direction.

Moreover, the thin portion 271 has the same thickness as the respective vibrating arms 28, 29, and 30 described later. The thick portion 272 is a portion in which the thickness in the Z-axis direction is larger than the thickness in the Z-axis direction of the respective vibrating arms 28, 29, and 30.

By forming such a thin portion 271 and such a thick portion 272, it is possible to decrease the thickness of the vibrating arms 28, 29, and 30 to thereby improve the vibration characteristics of the vibrating arms 28, 29, and 30 and to obtain the vibrator element 2 which can be manufactured with excellent handling properties.

Moreover, the three vibrating arms 28, 29, and 30 are connected to a side of the thin portion 271 of the base portion 27 opposite the thick portion 272.

The vibrating arms (first vibrating arms) 28 and 29 are connected to both ends of the base portion 27 in the X-axis direction, and the vibrating arm (second vibrating arm) 30 is connected to the central portion of the base portion 27 in the X-axis direction. The three vibrating arms 28, 29, and 30 are formed so as to extend in the Y-axis direction from the base portion 27 in parallel to each other. More specifically, the three vibrating arms 28, 29, and 30 are formed so as to extend in the Y-axis direction from the base portion 27 and be arranged in a line in the X-axis direction.

The vibrating arms 28, 29, and 30 have a longitudinal shape, end portions (base ends) close to the base portion 27 serving as a fixed end, and end portions (distal ends) on the opposite side of the base portion 27 serving as a free end. Moreover, the respective vibrating arms 28, 29, and 30 have a constant width over the entire range in the longitudinal direction. In addition, the respective vibrating arms 28, 29, and 30 may have a portion in which the width is different from that of other portions.

Moreover, the vibrating arms 28, 29, and 30 have the same length. In addition, the lengths of the vibrating arms 28, 29, and 30 are set in accordance with the widths, thicknesses, and the like of the respective vibrating arms 28, 29, and 30 and may be different from each other.

In addition, a mass portion (hammer head) having a larger cross-sectional area than the base end may be formed on the respective distal ends of the vibrating arms 28, 29, and 30 as necessary. In this case, it is possible to further decrease the size of the vibrator element 2 and further decrease the flexural vibration frequency of the vibrating arms 28, 29, and 30. Moreover, a weight for frequency adjustment may be formed on the respective distal ends of the vibrating arms 28, 29, and 30. In this case, by removing the weight formed on the respective vibrating arms 28, 29, and 30 of the vibrator element 2, it is possible to adjust the frequency of the vibrator element 2 to a predetermined value.

As shown in FIG. 4, the piezoelectric elements 22, 23, and 24 are formed on the vibrating arms 28, 29, and 30, respectively. Therefore, even when the directions of the polarization axes or the crystal axes of the vibrating arms 28, 29, and 30 are not ideal for the flexural vibration in the Z-axis direction, it is possible to allow the respective vibrating arms 28, 29, and 30 to perform flexural vibration in the Z-axis direction in a relatively simple and effective manner, regardless of whether the vibrating arms 28, 29, and 30 themselves have piezoelectric properties or not. Moreover, since the presence of the piezoelectric properties and the directions of the polarization axes or the crystal axes of the vibrating arms 28, 29, and 30 do not make any significant difference, the range of choice for the material of the respective vibrating arms 28, 29, and 30 widens. Thus, it is possible to realize the vibrator element 2 having desired vibration characteristics relatively easily.

The piezoelectric elements 22, 23, and 24 have a function of being expanded and compressed in response to a supply of current to cause the vibrating arms 28, 29, and 30 to perform flexural vibration in the Z-axis direction, respectively.

As shown in FIG. 4, such a piezoelectric element 22 has a configuration in which a first electrode layer 221, a piezoelectric layer (piezoelectric thin film) 222, and a second electrode layer 223 are stacked in that order on the vibrating arm 28. Similarly, the piezoelectric element 23 has a configuration in which a first electrode layer 231, a piezoelectric layer (piezoelectric thin film) 232, and a second electrode layer 233 are stacked in that order on the vibrating arm 29. Moreover, the piezoelectric element 24 has a configuration in which a first electrode layer 241, a piezoelectric layer (piezoelectric thin film) 242, and a second electrode layer 243 are stacked in that order on the vibrating arm 30.

Hereinafter, the respective layers constituting the respective piezoelectric elements 22, 23, and 24 are sequentially described. However, since the respective layers of the piezoelectric elements 23 and 24 have substantially the same configuration, the respective layers constituting the piezoelectric elements 22 and 24 will be described.

### Piezoelectric Element 22

First, the respective layers of the piezoelectric element 22 will be described.

### First Electrode Layer

As shown in FIG. 4, the first electrode layer 221 is formed on an upper surface 281 of the vibrating arm 28. Moreover, the first electrode layer 221 is formed on the vibrating arm 28 so as to extend from the base portion 27 along the extension direction (Y-axis direction) of the vibrating arm 28. In the present embodiment, the length of the first electrode layer 221 on the vibrating arm 28 is shorter than the length of the vibrating arm 28.

Moreover, in the present embodiment, the length of the first electrode layer 221 is set to be about ⅔ of the length of the vibrating arm 28. In addition, the length of the first electrode layer 221 can be set to be about ⅓ to 1 of the length of the vibrating arm 28.

Such a first electrode layer 221 can be formed of a metal material such as gold (Au), gold alloy, platinum (Pt), aluminum (Al), aluminum alloy, silver (Ag), silver alloy, chromium (Cr), chromium alloy, copper (Cu), molybdenum (Mo), niobium (Nb), tungsten (W), iron (Fe), titanium (Ti), cobalt (Co), zinc (Zn), or zirconium (Zr) and a transparent electrode material such as ITO or ZnO.

Among these materials, as the material of the first electrode layer 221, metal (gold and gold alloy) containing gold as its main component and platinum are preferred, and metal (particularly, gold) containing gold as its main component is more preferred.

Au is ideal for an electrode material due to its excellent conductive properties (small electrical resistance) and excellent resistance to oxidation. Moreover, Au can be easily patterned by etching as compared to Pt. Furthermore, by forming the first electrode layer 221 using gold or gold alloy, it is possible to improve the alignment properties of the piezoelectric layer 222.

Moreover, although the average thickness of the first electrode layer 221 is not particularly limited, the average thickness is preferably about 1 to 300 nm, for example, and more preferably is 10 to 200 nm, for example. With this configuration, it is possible to obtain the first electrode layer 221 having excellent conductive properties while preventing the first electrode layer 221 from exerting an adverse effect on the driving characteristics of the piezoelectric element 22 and the vibration characteristics of the vibrating arm 28.

For example, when the first electrode layer 221 is formed of gold and the vibration substrate 21 is formed of a quartz crystal, the adhesion properties between them are poor. Thus, in such a case, it is preferable to form an underlying layer formed of Ti or Cr between the first electrode layer 221 and the vibration substrate 21. With this configuration, it is possible to improve the adhesion properties between the underlying layer and the vibrating arm 28 and the adhesion properties between the underlying layer and the first electrode layer 221. As a result, it is possible to prevent the first electrode layer 221 from being separated from the vibrating arm and to improve the reliability of the vibrator element 2.

The average thickness of the underlying layer is not particularly limited as long as it can exhibit the effect of improving the adhesion properties as described above while preventing the underlying layer from exerting an adverse effect on the driving characteristics of the piezoelectric element 22 and the vibration characteristics of the vibrating arm 28. For example, the average thickness is preferably about 1 to 300 nm.

### Piezoelectric Layer

The piezoelectric layer 222 is formed on the first electrode layer 221 so as to extend along the extension direction (Y-axis direction) of the vibrating arm 28.

Moreover, the length of the piezoelectric layer 222 in the extension direction (Y-axis direction) of the vibrating arm 28 is approximately the same as the length of the first electrode layer 221 in the same direction (Y-axis direction).

With this configuration, it is possible to improve the alignment properties of the piezoelectric layer 222 over the entire area of the piezoelectric layer 222 in the Y-axis direction due to the surface state of the first electrode layer 221 as described above. Therefore, it is possible to make the piezoelectric layer 222 homogeneous in the longitudinal direction (Y-axis direction) of the vibrating arm 28.

Examples of the material of such a piezoelectric layer 222 include zinc oxide (ZnO), aluminum nitride (AlN), lithium tantalate (LiTaO₃), lithium niobate (LiNbO₃), potassium niobate (KNbO₃), lithium tetraborate (Li₂B₄O₇), barium titanate (BaTiO₃), and lead zirconate titanate (PZT). Among these materials, AlN and ZnO are preferably used.

Among these materials, ZnO and AlN are preferably used as the material of the piezoelectric layer 222. The ZnO (zinc oxide) and AlN (aluminum nitride) exhibit excellent c-axis alignment properties. Thus, by forming the piezoelectric layer 222 using ZnO as its main component, it is possible to decrease the CI value of the vibrator element 2. Moreover, these materials can be deposited by a reactive sputtering method.

Moreover, the average thickness of the piezoelectric layer 222 is preferably 50 to 3000 nm, and more preferably is 200 to 2000 nm. With this configuration, it is possible to obtain the piezoelectric element 22 having excellent driving characteristics while preventing the piezoelectric layer 222 from exerting an adverse effect on the vibration characteristics of the vibrating arm 28.

### Second Electrode Layer

The second electrode layer 223 is formed on the piezoelectric layer 222 so as to extend in the extension direction (Y-axis direction) of the vibrating arm 28. Moreover, the length of the second electrode layer 223 in the extension direction (Y-axis direction) of the vibrating arm 28 is approximately the same as the length of the piezoelectric layer 222. With this configuration, the entire area of the piezoelectric layer 222 in the extension direction (Y-axis direction) of the vibrating arm 28 can be expanded and compressed by an electric field generated between the second electrode layer 223 and the first electrode layer 221 described above. Thus, it is possible to improve vibration efficiency.

Such a second electrode layer 223 can be formed of a metal material such as gold (Au), gold alloy, platinum (Pt), aluminum (Al), aluminum alloy, silver (Ag), silver alloy, chromium (Cr), chromium alloy, copper (Cu), molybdenum (Mo), niobium (Nb), tungsten (W), iron (Fe), titanium (Ti), cobalt (Co), zinc (Zn), or zirconium (Zr) and a transparent electrode material such as ITO or ZnO. In particular, similarly to the first electrode layer 221, as the material of the second electrode layer 223, metal (gold and gold alloy) containing gold as its main component and platinum are preferred, and metal (particularly, gold) containing gold as its main component is more preferred.

Moreover, although the average thickness of the second electrode layer 223 is not particularly limited, the average thickness is preferably about 1 to 300 nm, for example, and more preferably is 10 to 200 nm, for example. With this configuration, it is possible to obtain the second electrode layer 223 having excellent conductive properties while preventing the second electrode layer 223 from exerting an adverse effect on the driving characteristics of the piezoelectric element 22 and the vibration characteristics of the vibrating arm 28.

In addition, an insulating layer formed of SiO₂ (silicon oxide) or AlN (aluminum nitride) may be formed between the piezoelectric layer 222 and the second electrode layer 223 as necessary. This insulating layer has a function of protecting the piezoelectric layer 222 and preventing short-circuiting between the first and second electrode layers 221 and 223. Moreover, the insulating layer may be formed so as to cover only the upper surface of the piezoelectric layer 222 and may be formed so as to cover the side surfaces (surfaces other than a surface contacting the first electrode layer 221) of the piezoelectric layer 222 as well as the upper surface of the piezoelectric layer 222.

Although the average thickness of the insulating layer is not particularly limited, the average thickness is preferably 50 to 500 nm. If the thickness is less than the lower limit, the effect of preventing short-circuiting tends to weaken. On the other hand, if the thickness is more than the upper limit, the insulating layer may exert an adverse effect on the characteristics of the piezoelectric element 22.

In such a piezoelectric element 22, when a voltage is applied between the first and second electrode layers 221 and 223, an electric field in the Z-axis direction is generated in the piezoelectric layer 222. In response to the electric field, the piezoelectric layer 222 is expanded and compressed in the Y-axis direction, and the vibrating arm 28 performs flexural vibration in the Z-axis direction.

Similarly, in the piezoelectric element 23, when a voltage is applied between the first and second electrode layers 231 and 233, the piezoelectric layer 232 is expanded and compressed in the Y-axis direction, and the vibrating arm 29 performs flexural vibration in the Z-axis direction.

### Piezoelectric Element 24

Subsequently, the respective layers of the piezoelectric element 24 will be described. Description of the same configurations as the respective layers of the piezoelectric element 22 will be omitted.

### First Electrode Layer

As shown in FIG. 4, the first electrode layer 241 is formed on a lower surface 302 of the vibrating arm 30. Moreover, the first electrode layer 241 is formed on the vibrating arm 30 so as to extend from the base portion 27 along the extension direction (Y-axis direction) of the vibrating arm 30. Since the material, the length, the average thickness, and the like of the first electrode layer 241 are the same as those of the first electrode layer 221, description thereof will be omitted.

### Piezoelectric Layer

As shown in FIG. 4, the piezoelectric layer 242 has an annular (cylindrical) shape and is formed along the extension direction (Y-axis direction) of the vibrating arm 30 while covering (surrounding) the outer circumference of the vibrating arm 30 excluding the distal end thereof.

The length of the piezoelectric layer 242 in the extension direction (Y-axis direction) of the vibrating arm is approximately the same as the length of the first electrode layer 241 in the same direction. With this configuration, it is possible to improve the alignment properties of the piezoelectric layer 242 over the entire area of the piezoelectric layer 242 in the Y-axis direction due to the surface state of the first electrode layer 241 as described above. Therefore, it is possible to make the piezoelectric layer 242 homogeneous in the longitudinal direction (Y-axis direction) of the vibrating arm 30.

As described above, since the piezoelectric layer 242 is formed so as to cover a part of the outer circumference of the vibrating arm 30, the piezoelectric layer 242 includes a first portion 242a positioned close to the lower surface 302 (on the first electrode layer 241) of the vibrating arm 30 and a second portion 242b positioned close to the upper surface 301 of the vibrating arm 30. As above, since the piezoelectric layer 242 includes the second portion 242b, it is possible to connect the piezoelectric layer 242 to the insulating layer 55 easily without any steps as will be described later.

Although the average thickness of the first portion 242a is not particularly limited, the average thickness is preferably approximately the same as the average thickness of the piezoelectric layer 222. Moreover, although the average thickness of the second portion 242b is not particularly limited, the average thickness is preferably set to a thickness such that the upper surface thereof is formed on the same plane as the upper surface of the piezoelectric layer 222. That is, the average thickness is preferably approximately the same as the sum of the average thickness of the first electrode layer 221 and the average thickness of the piezoelectric layer 222.

The same material as the piezoelectric layer 222 can be used as the material (piezoelectric material) of the piezoelectric layer 242.

### Second Electrode Layer

As shown in FIG. 4, the second electrode layer 243 has an annular (cylindrical) shape and is formed along the extension direction (Y-axis direction) of the vibrating arm 30 while covering the outer circumference of the piezoelectric layer 242.

Moreover, the length of the second electrode layer 243 in the extension direction (Y-axis direction) of the vibrating arm 30 is approximately the same as the length of the piezoelectric layer 242. With this configuration, the entire area of the first portion 242a of the piezoelectric layer 242 in the extension direction (Y-axis direction) of the vibrating arm 30 can be expanded and compressed by an electric field generated between the second electrode layer 243 and the first electrode layer 241 described above. Thus, it is possible to improve vibration efficiency.

As described above, since the second electrode layer 243 is formed so as to cover a part of the outer circumference of the piezoelectric layer 242, the second electrode layer 243 includes a first portion 243a positioned close to the lower surface 302 (on the first portion 242a of the piezoelectric layer 242) of the vibrating arm 30 and a second portion 243b positioned close to the upper surface 301 (on the second portion 242b of the piezoelectric layer 242) of the vibrating arm 30. As above, since the second electrode layer 243 includes the second portion 243b, it is possible to connect the second electrode layer 243 to the second wiring layer 52 easily without any steps as will be described later. In addition, in FIG. 4, although both the piezoelectric layer 242 and the second electrode layer 243 are formed in an annular shape so as to cover a part of the outer circumference, only the second electrode layer 243 may be formed in an annular shape so as to cover a part of the outer circumference. In this case, although a step is formed between the second electrode layer 243 and the second wiring layer 52, when the step is formed in a slope shape, it is possible to decrease the step angle and to suppress short-circuiting of a wiring pattern.

Since the material or the average thickness of the second electrode layer 243 are the same as those of the second electrode layer 223, description thereof will be omitted.

In the piezoelectric element 24 having such a configuration, when a voltage is applied between the first and second electrode layers 241 and 243, an electric field in the Z-axis direction is generated in the first portion 242a (a portion positioned between the first electrode layer 241 and the first portion 243a of the second electrode layer 243) of the piezoelectric layer 242. In response to the electric field, the first portion 242a of the piezoelectric layer 242 is expanded and compressed in the Y-axis direction, and the vibrating arm 30 performs flexural vibration in the Z-axis direction.

As above, in the piezoelectric element 24, a portion which is expanded and compressed to thereby cause the vibrating arm 30 to perform flexural vibration in the Y-axis direction is made up of the first electrode layer 241, the first portion 243a of the second electrode layer 243, and the first portion 242a of the piezoelectric layer 242 positioned between the first electrode layer 241 and the first portion 243a. That is, the portion is a region S surrounded by the dotted line in FIG. 4. From the above, the piezoelectric element 24 can be said to be formed close to the lower surface (second surface) 302 of the vibrating arm 30.

Hereinabove, the configuration of the piezoelectric elements 22, 23, and 24 has been described in detail.

As shown in FIGS. 2 and 5, a stacked structure in which the first wiring layer 51, the second wiring layer 52, and the insulating layer 55 positioned between these two wiring layers 51 and 52 so as to electrically isolate the two wiring layers 51 and 52 are stacked is formed on the upper surface 27a of the base portion 27. Moreover, as shown in FIG. 3, the third wiring layer 53 is formed on the lower surface 27b of the base portion 27. Moreover, the fourth wiring layer 54 is formed on the side surface 27c of the base portion 27. By forming these respective layers 51 to 55, it is possible to easily perform electrical extraction of the first electrode layers 221, 231, and 241 and the second electrode layers 223, 233, and 243 of the respective piezoelectric elements 22, 23, and 24 as will be described later.

Hereinafter, the configuration of the respective layers will be sequentially described in detail.

### First Wiring Layer

FIG. 5 is a planar view of the vibrator element 2 as seen from the upper surface, in which the second wiring layer 52 and the insulating layer 55 are not illustrated. As shown in FIG. 5, the first wiring layer 51 is formed on the upper surface 27a of the base portion 27. Such a first wiring layer includes a wiring portion 511 and a first connection electrode 512 which are electrically connected to each other.

The wiring portion 511 is electrically connected to the first electrode layer 221 of the piezoelectric element 22 formed on the vibrating arm 28 at the upper surface 27a of the base portion 27. The wiring portion 511 is also electrically connected to the first electrode layer 231 of the piezoelectric element 23 formed on the vibrating arm 29 at the upper surface 27a. With this configuration, the first electrode layers 221 and 231 are electrically connected to the first connection electrode 512 through the wiring portion 511.

With such a configuration, it is possible to form the first wiring layer 51 without any steps and to connect the first wiring layer 51 to the first electrode layers 221 and 231 without any step. That is, the first wiring layer 51 and the first electrode layers 221 and 231 can be formed planarly (on the same plane). More specifically, it is possible to connect the first wiring layer 51 and the first electrode layers 221 and 231 without forming a contact hole as in the case of a vibrator element of the related art. Thus, it is possible to effectively prevent short-circuiting in the middle of the first wiring layer 51 and at the boundary (joint) between the first wiring layer 51 and the first electrode layers 221 and 231. Thus, these respective layers can be electrically connected in a more reliable and easy manner.

The first wiring layer 51 can be formed of a metal material such as gold (Au), gold alloy, platinum (Pt), aluminum (Al), aluminum alloy, silver (Ag), silver alloy, chromium (Cr), chromium alloy, copper (Cu), molybdenum (Mo), niobium (Nb), tungsten (W), iron (Fe), titanium (Ti), cobalt (Co), zinc (Zn), or zirconium (Zr) and a transparent electrode material such as ITO or ZnO.

Moreover, the first wiring layer 51 can be formed at once at the same time as the first electrode layers 221 and 231.

### Insulating Layer

As shown in FIG. 2, the insulating layer 55 is positioned between the first wiring layer 51 and the second wiring layer 52 and has a function of electrically isolating the first wiring layer 51 from the second wiring layer 52. The insulating layer 55 is formed on the upper surface 27a so as to cover at least apart (in particular, the periphery including a portion crossing the second wiring layer 52) of the wiring portion 511 while exposing the first connection electrode 512 of the first wiring layer 51 to the outside of the vibrator element 2.

The insulating layer 55 is connected to the piezoelectric layer 222 of the piezoelectric element 22 formed on the vibrating arm 28 at the upper surface 27a of the base portion 27 and is also connected to the piezoelectric layer 232 of the piezoelectric element 23 formed on the vibrating arm 29. In addition, the insulating layer 55 is connected to the second portion 242b of the piezoelectric layer 242 of the piezoelectric element 24 formed on the vibrating arm 30 at the upper surface 27a of the base portion 27. With this configuration, it is possible to cover the first wiring layer 51 with the insulating layer 55 as described above and to electrically isolate the first wiring layer 51 from the second wiring layer 52 in a more reliable manner.

The upper surface 551 of the insulating layer 55 is positioned on the same plane as the upper surfaces of the piezoelectric layers 222, 232, and 242 (as for the piezoelectric layer 242, the second portion 242b). With this configuration, no step is formed at the boundary between the insulating layer 55 and the piezoelectric layers 222, 232, and 242 (as for the piezoelectric layer 242, the second portion 242b), and the second wiring layer 52 can be easily formed on the upper surface 551 of the insulating layer 55.

In the present embodiment, the insulating layer 55 is formed integrally of the same material as the respective piezoelectric layers 222, 232, and 242. With this configuration, the insulating layer 55 can be formed in a simple manner, and as described above, the insulating layer 55 and the upper surfaces of the piezoelectric layers 222, 232, and 242 (as for the piezoelectric layer 242, the second portion 242b) can be formed on the same plane in a simple manner. Furthermore, it is possible to effectively prevent or suppress the occurrence of a step or the like at the boundary between the insulating layer 55 and the respective piezoelectric layers 222, 232, and 242.

In addition, the material of the insulating layer 55 is not particularly limited as long as it has insulating properties, and for example, a resin material or the like may be used.

### Second Wiring Layer

As shown in FIG. 2, the entire area of the second wiring layer 52 is formed on the upper surface 551 of the insulating layer 55. Such a second wiring layer 52 includes a wiring portion 521 and a second connection electrode 522 which are electrically connected to each other.

The wiring portion 521 is electrically connected to the second electrode layer 223 of the piezoelectric element 22 formed on the vibrating arm 28 at the upper surface 551 of the insulating layer 55 and is also electrically connected to the second electrode layer 233 of the piezoelectric element 23 formed on the vibrating arm 29. Furthermore, the wiring portion 521 is electrically connected to the second portion 243b of the second electrode layer 243 of the piezoelectric element 24 formed on the vibrating arm 30 at the upper surface 551 of the insulating layer 55. With this configuration, the second electrode layers 223, 233, and 243 are electrically connected to the second connection electrode 522 through the wiring portion 521.

With such a configuration, it is possible to form the second wiring layer 52 without any steps and to connect the second wiring layer 52 to the second electrode layers 223, 233, and 243 without any step. That is, the second wiring layer 52 and the second electrode layers 223, 233, and 243 (as for the second electrode layer, the second portion 243b) can be formed planarly (on the same plane). More specifically, it is possible to connect the second wiring layer 52 and the second electrode layers 223, 233, and 243 without forming a contact hole as in the case of a vibrator element of the related art. Thus, it is possible to effectively prevent short-circuiting in the middle of the second wiring layer 52 and at the boundary (joint) between the second wiring layer 52 and the second electrode layers 223, 233, and 243. Thus, these respective layers can be electrically connected in a more reliable and easy manner.

In addition, the wiring portion 521 is preferably disposed so as not to overlap with the wiring portion 511 of the first wiring layer 51. As described above, when the insulating layer 55 is formed of a piezoelectric material, a portion of the insulating layer 55 interposed between the wiring portion 511 and the wiring portion 521 may be expanded and compressed by a piezoelectric effect, so that unintended vibration may occur in the vibrator element 2. However, by disposing the wiring portion 521 so as not to overlap with the wiring portion 511 as much as possible, it is possible to effectively suppress the occurrence of such vibration.

Such a second wiring layer 52 can be formed of a metal material such as gold (Au), gold alloy, platinum (Pt), aluminum (Al), aluminum alloy, silver (Ag), silver alloy, chromium (Cr), chromium alloy, copper (Cu), molybdenum (Mo), niobium (Nb), tungsten (W), iron (Fe), titanium (Ti), cobalt (Co), zinc (Zn), or zirconium (Zr) and a transparent electrode material such as ITO or ZnO.

Moreover, the second wiring layer 52 can be formed at once at the same time as the second electrode layers 223, 233, and 243.

### Third Wiring Layer

As shown in FIG. 3, the third wiring layer 53 is formed on the lower surface 27b of the base portion 27. Such a third wiring layer 53 is electrically connected to the first electrode layer 241 of the piezoelectric element 24 formed on the vibrating arm 30 at the lower surface 27b of the base portion 27.

With such a configuration, it is possible to form the third wiring layer 53 without any steps (excluding a step resulting from the outer shape of the vibration substrate 21) and to connect the third wiring layer 53 to the first electrode layer 241 without any step. Therefore, it is possible to connect the third wiring layer 53 and the first electrode layer 241 without forming a contact hole as in the case of a vibrator element of the related art. Thus, it is possible to effectively prevent short-circuiting in the middle of the third wiring layer 53 and at the boundary (joint) between the third wiring layer 53 and the first electrode layer 241. Thus, these respective layers can be electrically connected in a more reliable and easy manner.

The third wiring layer 53 can be formed of a metal material such as gold (Au), gold alloy, platinum (Pt), aluminum (Al), aluminum alloy, silver (Ag), silver alloy, chromium (Cr), chromium alloy, copper (Cu), molybdenum (Mo), niobium (Nb), tungsten (W), iron (Fe), titanium (Ti), cobalt (Co), zinc (Zn), or zirconium (Zr) and a transparent electrode material such as ITO or ZnO.

Moreover, the third wiring layer 53 can be formed at the same time as the first electrode layer 241: that is, it can be formed at once at the same time as the first wiring layer 51.

### Fourth Wiring Layer

As shown in FIG. 2, the fourth wiring layer 54 is formed on the side surface 27c of the base portion 27. Due to the fourth wiring layer 54, the third wiring layer 53 is electrically connected to the first wiring layer 51 (the first connection electrode 512). In this way, the first electrode layers 221, 231, and 241 of the respective piezoelectric elements 22, 23, and 24 are electrically connected to the first wiring layer 51 (the first connection electrode 512).

The fourth wiring layer 54 can be formed of a metal material such as gold (Au), gold alloy, platinum (Pt), aluminum (Al), aluminum alloy, silver (Ag), silver alloy, chromium (Cr), chromium alloy, copper (Cu), molybdenum (Mo), niobium (Nb), tungsten (W), iron (Fe), titanium (Ti), cobalt (Co), zinc (Zn), or zirconium (Zr) and a transparent electrode material such as ITO or ZnO.

Moreover, the fourth wiring layer 54 can be formed at once at the same time as the first wiring layer 51 or the third wiring layer 53.

The vibrator element 2 having such a configuration is driven in the following manner. That is, when a voltage (a voltage for vibrating the respective vibrating arms 28, 29, and 30) is applied between the first connection electrode 512 and the second connection electrode 522, a voltage in the Z-axis direction is applied to the piezoelectric layers 222, 232, and 242 (as for the piezoelectric layer 242, the first portion 242a) so that the first electrode layers 221, 231, and 241 and the second electrode layers 223, 233, and 243 have the opposite polarities.

In this way, due to a reverse piezoelectric effect of the piezoelectric material, the respective vibrating arms 28, 29, and 30 perform flexural vibration at a certain constant frequency (resonance frequency). In this case, as shown in FIG. 6, the vibrating arms (first vibrating arms) 28 and 29 perform flexural vibration in the same directions, and the vibrating arm (second vibrating arm) 30 performs flexural vibration in the opposite direction to that of the vibrating arms 28 and 29.

Moreover, as described above, when the respective vibrating arms 28, 29, and 30 perform flexural vibration, a voltage is generated between the first and second connection electrodes 512 and 532 at a certain constant frequency due to the piezoelectric effect of the piezoelectric material. By using these properties, the vibrator element 2 can generate an electrical signal that vibrates at the resonance frequency.

As described above, since the vibrator element 2 includes the vibrating arms (first vibrating arms) 28 and 29 having the piezoelectric element formed on the upper surface thereof and the vibrating arm (second vibrating arm) 30 having the piezoelectric element formed on the lower surface thereof, the vibrator element 2 can exhibit excellent vibration characteristics. This will be explained in detail below.

FIG. 7A shows the configuration of the related art, namely a configuration in which the piezoelectric elements formed on the respective vibrating arms 28, 29, and 30 are formed on the sides of the upper surfaces 281, 291, and 301 of the vibrating arms thereof. A chain line L1 in FIG. 7A indicates the positions of the centers of all of the vibrating arms 28, 29, and 30 when no piezoelectric element is formed. A chain line L2 indicates the positions of the centers of all of the vibrating arms 28, 29, and 30 including the piezoelectric elements when the piezoelectric elements are formed on the respective vibrating arms 28, 29, and 30.

On the other hand, FIG. 7B shows the vibrator element 2 of the present embodiment, in which chain lines L1 and L2 have the same meaning as the chain lines L1 and L2 in FIG. 7A. As is obvious from comparison between FIGS. 7A and 7B, in the vibrator element 2 of the present embodiment shown in FIG. 7B, the amount of shift in the Z-axis direction of the centers of all of the vibrating arms 28, 29, and 30 including the piezoelectric element is smaller than that of the vibrator element of the related art shown in FIG. 7A. That is, in the vibrator element 2, it is possible to effectively absorb the shift in the Z-axis direction of the centers. Thus, the vibrator element 2 can cause the respective vibrating arms 28, 29, and 30 to perform flexural vibration in the Z-axis direction in a well-balanced manner. As a result, the vibrator element 2 can exhibit excellent vibration characteristics.

In the vibrator element 2, the above-described configuration is realized by forming the piezoelectric elements 22 and 23 close to the upper surfaces (first surfaces) 281 and 291 of the vibrating arms (first vibrating arms) 28 and 29 and forming the piezoelectric element 24 close to the lower surface (second surface) 302 of the vibrating arm (second vibrating arm) 30. With this configuration, the configuration of the vibrator element 2 becomes simpler.

Here, it is preferable that the number of first vibrating arms be the same as the number of second vibrating arms or the difference between the two numbers be 1. That is when the number of vibrating arms is an odd number, it is preferable that the difference between the number of first vibrating arms and the number of second vibrating arms be 1. When the number of vibrating arms is an even number, it is preferable that the number of first vibrating arms be the same as the number of second vibrating arms. With this configuration, it is possible to suppress a shift of center as described above more effectively and to obtain the vibrator element 2 capable of exhibiting more excellent vibration characteristics.

In addition, the vibrator element 2 includes the first and second vibrating arms which are alternately arranged in the X-axis direction so as to perform flexural vibration in the opposite directions to each other. Thus, by allowing two adjacent vibrating arms to perform flexural vibration in the opposite directions to each other, it is possible to cancel leakage vibration caused by two adjacent vibrating arms 28 and 30 and 29 and 30. As a result, it is possible to prevent vibration leakage.

Moreover, in the vibrator element 2, the first electrode layers 221 and 231 are formed on the upper surfaces (first surfaces) 281 and 291 of the first vibrating arms 28 and 29, and the first electrode layer 241 is formed on the lower surface (second surface) 302 of the second vibrating arm 30. In this way, by forming the three first electrode layers 221, 231, and 241 electrically connected to each other closest to the vibration substrate 21 among the three layers (the first electrode layer, the piezoelectric layer, and the second electrode layer) constituting the respective piezoelectric elements 22, 23, and 24, it is possible to connect these electrode layers without any steps (excluding a step resulting from the outer shape of the vibration substrate 21) using the first, third, and fourth wiring layers 51, 53, and 54.

Hereinabove, the configuration of the vibrator element 2 has been described in detail.

### Method of Manufacturing Vibrator Element

An example of a method of manufacturing the vibrator element 2 will be described briefly.

A method of manufacturing the vibrator element 2 includes: a process A of forming the first electrode layers 221, 231, and 241 on the vibrating arms 28, 29, and 30 and forming the first, third, and fourth wiring layers 51, 53, and 54 on the base portion 27; a process B of forming the piezoelectric layers 222, 232, and 242 on the first electrode layers 221, 231, and 241 and forming the insulating layer 55 on the base portion 27; and a process C of forming the second electrode layers 223, 233, and 243 on the piezoelectric layers 222, 232, and 242 and forming the second wiring layers 52 on the insulating layer 55.

Hereinafter, the respective processes will be described briefly.

### Process A

First, a substrate for forming the vibration substrate 21 is prepared.

Moreover, the substrate is etched to form the vibration substrate 21.

More specifically, for example, when the substrate is a quartz crystal substrate, a portion of the quartz crystal substrate serving as the thin portion 271 is removed by anisotropic etching using BHF (buffer hydrogen fluoride) as an etching solution to decrease the thickness thereof. After that, the thin portion is partially removed by the same anisotropic etching as above to form the vibrating arms 28, 29, and 30. In this way, the vibration substrate 21 is formed.

After that, the first electrode layers 221, 231, and 241 are formed on the vibrating arms 28, 29, and 30, and the first, third, and fourth wiring layers 51, 53, and 54 are formed on the base portion 27. In this case, the first electrode layers 221, 231, and 241 and the first, third, and fourth wiring layers 51, 53, and 54 can be formed at once by the same deposition process as described below.

The respective layers 221, 231, 241, 51, 53, and 54 can be formed by various deposition methods such as a vapor deposition method, such as a physical deposition method (for example, a sputtering method, a vacuum deposition method, and the like), a chemical deposition method (for example, CVD (Chemical Vapor Deposition)), or an ink jet method. Among these methods, a vapor deposition method (in particular, a sputtering method or a vacuum deposition method) is preferably used. Moreover, it is preferable to use a photolithographic method when forming the respective layers 221, 231, 241, 51, 53, and 54.

### Process B

Subsequently, the piezoelectric layers 222 and 232 are formed on the first electrode layers 221 and 231, the piezoelectric layer 242 is formed so as to surround the outer circumference of the vibrating arm 30 and the first electrode layer 241, and the insulating layer 55 is formed on the base portion 27 so as to cover at least a part of the wiring portion 511 of the first wiring layer 51. In this case, the piezoelectric layers 222, 232, and 242 and the insulating layer 55 can be formed at once by the same deposition process as shown below.

The respective layers 222, 232, 242, and 55 can be formed by various deposition methods such as a vapor deposition method, such as a physical deposition method (for example, a sputtering method, a vacuum deposition method, and the like), a chemical deposition method (for example, CVD (Chemical Vapor Deposition)), or an ink jet method. Among these methods, a vapor deposition method (in particular, a reactive sputtering method) is preferably used. Moreover, it is preferable to use a photolithographic method when forming (patterning) the respective layers 222, 232, 242, and 55. Moreover, it is preferable to remove an unnecessary portion by wet-etching when patterning the respective layers 222, 232, 242, and 55.

### Process C

Subsequently, the second electrode layers 223 and 233 are formed on the piezoelectric layers 222 and 232, the second electrode layer 243 is formed so as to surround the outer circumference of the piezoelectric layer 242, and the second wiring layer 52 is formed on the insulating layer 55. In this case, the second electrode layers 223, 233, and 243 and the second wiring layer 52 can be formed at once by the same deposition process as described below.

The respective layers 223, 233, 243 and 52 can be formed by various deposition methods such as a vapor deposition method, such as a physical deposition method (for example, a sputtering method, a vacuum deposition method, and the like), a chemical deposition method (for example, CVD (Chemical Vapor Deposition)), or an ink jet method. Among these methods, a vapor deposition method (in particular, a sputtering method or a vacuum deposition method) is preferably used. Moreover, it is preferable to use a photolithographic method when forming the respective layers 223, 233, 243 and 52.

In this way, the vibrator element 2 can be manufactured.

### Package

Next, a package 3 in which the vibrator element 2 is accommodated and fixed will be described.

As shown in FIG. 1, the package 3 includes a planar base substrate 31, a frame-shaped member 32, and a planar lid member 33. The base substrate 31, the frame member 32, and the lid member 33 are stacked in that order from bottom to top. The base substrate 31 and the frame member 32 are formed of a ceramics material or the like described later and are bonded together by baking. Moreover, the frame member 32 and the lid member 33 are bonded by an adhesive agent, a soldering material, or the like. Moreover, the package 3 includes the vibrator element 2 which is accommodated in an inner space S defined by the base substrate 31, the frame member 32, and the lid member 33. In addition to the vibrator element 2, electronic components (oscillation circuit) or the like for driving the vibrator element 2 can be accommodated in the package 3.

As the material of the base substrate 31, materials having insulating properties (non-conductive properties) are preferred. Examples of such materials include various types of glass, various types of ceramics materials such as oxide ceramics, nitride ceramics, or carbide ceramics, and various types of resin materials such as polyimide.

Moreover, as the materials of the frame member 32 and the lid member 33, the same material as the base substrate 31, various types of metal materials such as Al or Cu, various glass materials, and the like can be used, for example.

The vibrator element 2 described above is fixed to the upper surface of the base substrate 31 by a fixing member 36. The fixing member 36 is formed of an adhesive agent such as, for example, epoxy-based adhesive, polyimide-based adhesive, or silicon-based adhesive. Such a fixing member 36 is formed by applying a non-cured (non-solidified) adhesive onto the base substrate 31, mounting the vibrator element 2 on the adhesive, and then curing or solidifying the adhesive. In this way, the vibrator element 2 (the base portion 27) is reliably fixed to the base substrate 31.

In addition, the fixing may be performed by using a conductive adhesive agent, such as epoxy-based adhesive, polyimide-based adhesive, or silicon-based adhesive, containing conductive particles.

Moreover, a pair of electrodes 35a and 35b is formed on the upper surface of the base substrate 31 so as to be exposed to the inner space S.

The electrode 35a is electrically connected to the second connection electrode 522 described above through metal wires (bonding wires) 38 that are formed by wire bonding technique, for example. Moreover, the electrode 35b is electrically connected to the first connection electrode 512 described above through metal wires (bonding wires) 37 that are formed by wire bonding technique, for example.

In addition, a method of connecting the pair of electrodes 35a and 35b and the first and second connection electrodes 512 and 522 is not limited to the above method, and the electrodes may be connected by a conductive adhesive agent, for example. In this case, the vibrator element 2 may be turned upside down from the illustrated state, or the first and second connection electrodes 512 and 522 may be formed on the lower surface of the vibrator element 2.

Moreover, four external terminals 34a, 34b, 34c, and 34d are formed on the lower surface of the base substrate 31.

Among these four external terminals 34a to 34d, the external terminals 34a and 34b are hot terminals which are electrically connected to the electrodes 35a and 35b through conductor posts (not shown) formed in via-holes which are formed in the base substrate 31, respectively. Moreover, the other two external terminals 34c and 34d are dummy terminals for increasing the bonding strength when mounting the package 3 on a mounting substrate or making the distance between the package 3 and the mounting substrate constant.

These electrodes 35a and 35b and the external terminals 34a to 34d can be formed by plating an underlying layer of tungsten and nickel with gold, for example.

When electronic components are accommodated in the package 3, writing terminals for testing properties of the electronic components and rewriting (adjusting) various types of internal information (for example, temperature-compensation information of a vibrator) of the electronic components may be provided on the lower surface of the base substrate 31 as necessary.

According to the first embodiment described hereinabove, the vibrating arm 28, 29, and 30 can perform flexural vibration in a well-balanced and smooth manner. Thus, the vibrator element 2 capable of exhibiting excellent vibration characteristics is obtained.

Moreover, the vibrator 1 having such a vibrator element 2 exhibits excellent reliability.

### Second Embodiment

Next, a second embodiment of the invention will be described.

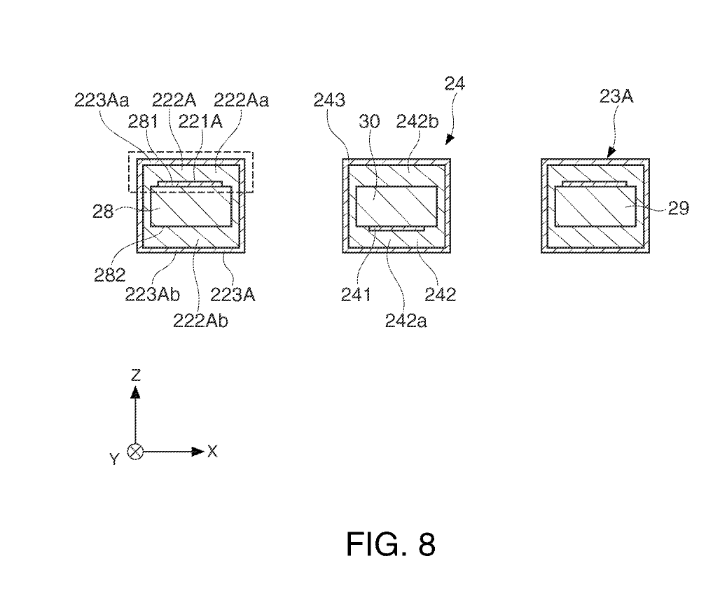

FIG. 8 is a cross-sectional view illustrating a vibrator element according to the second embodiment of the invention. FIG. 8 corresponds to the cross-sectional view taken along the line A-A in FIG. 2.

Hereinafter, the second embodiment will be described focusing on the difference from the above-described embodiment, and the same portions will not be described.

The second embodiment is substantially the same as the first embodiment, except that the configuration of the piezoelectric elements formed on the vibrating arms (first vibrating arms) 28 and 29 are different from that of the first embodiment. In FIG. 8, the same configurations as the above-described embodiment will be denoted by the same reference numerals. Moreover, in the present embodiment, although a piezoelectric element 22A formed on the vibrating arm 28 will be describe as a representative, the same is applied to a piezoelectric element 23A formed on the vibrating arm 29.

As shown in FIG. 8, the piezoelectric element 22A includes a first electrode layer 221A, a piezoelectric layer 222A, and a second electrode layer 223A, and has a shape corresponding to the piezoelectric element 24.

That is, the first electrode layer 221A is formed on the upper surface 281 of the vibrating arm 28, the piezoelectric layer 222A is formed so as to cover the outer circumference of the vibrating arm 28 and the first electrode layer 221A, and the second electrode layer 223A is formed so as to cover the outer circumference of the piezoelectric layer 222A.

The piezoelectric layer 222A includes a first portion 222Aa positioned close to the upper surface 281 of the vibrating arm 28 and a second portion 222Ab positioned close to the lower surface 282 of the vibrating arm 28. Similarly, the second electrode layer 223A includes a first portion 223Aa positioned close to the upper surface 281 of the vibrating arm 28 and a second portion 223Ab positioned close to the lower surface 282 of the vibrating arm 28.

In the piezoelectric element 22A having such a configuration, when a voltage is applied between the first electrode layer 221A and the second electrode layer 223A, an electric field in the Z-axis direction is generated in the first portion 222Aa of the piezoelectric layer 222A. In response to this electric field, the first portion 222Aa of the piezoelectric layer 222A is expanded or compressed in the Y-axis direction, and the vibrating arm 28 performs flexural vibration in the Z-axis direction.

As above, in the piezoelectric element 22A, a portion which is expanded and compressed to thereby cause the vibrating arm 28 to perform flexural vibration in the Y-axis direction is made up of the first electrode layer 221A, the first portion 223Aa of the second electrode layer 223A, and the first portion 222Aa of the piezoelectric layer 222A positioned between the first electrode layer 221A and the first portion 223Aa. That is, the portion is a region surrounded by the dotted line in FIG. 8. From the above, the piezoelectric element 22A can be said to be formed close to the upper surface 281 of the vibrating arm 28.

As in the present embodiment, by configuring the respective piezoelectric elements 22, 23, and 24 so as to have the corresponding configuration, namely a configuration in which each piezoelectric element includes the first electrode layer formed on one surface of the vibrating arm, the piezoelectric layer formed so as to cover the outer circumference of the vibrating arm, and the second electrode layer, it is possible to achieve weight balance between the piezoelectric elements 22, 23, and 24. In this way, the vibrating arms 28, 29, and 30 can perform flexural vibration more smoothly.

Moreover, the second embodiment as described above can exhibit the same advantageous effects as the first embodiment described above.

### Third Embodiment

Next, a third embodiment of the invention will be described.

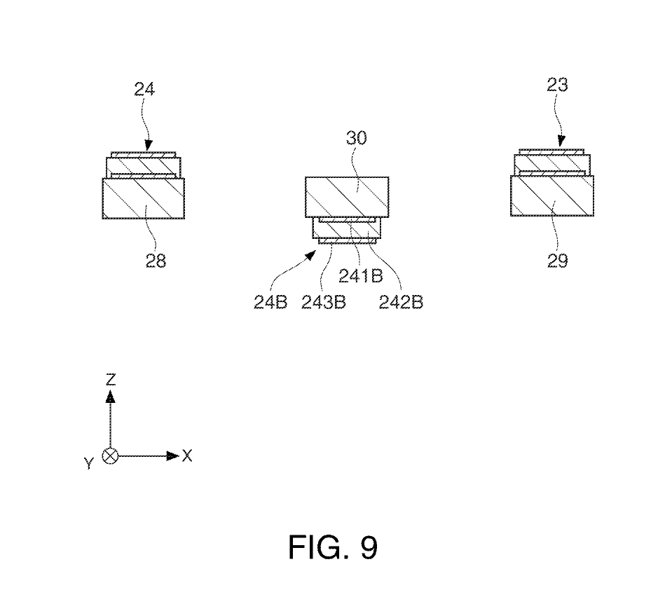

FIG. 9 is a cross-sectional view illustrating a vibrator element according to a third embodiment of the invention.

FIG. 9 corresponds to the cross-sectional view taken along the line A-A in FIG. 2.

Hereinafter, the third embodiment will be described focusing on the difference from the above-described embodiment, and the same portions will not be described.

The third embodiment is substantially the same as the first embodiment, except that the configuration of the piezoelectric element formed on the vibrating arm (second vibrating arm) 30 is different from that of the first embodiment. In FIG. 9, the same configurations as the above-described embodiment will be denoted by the same reference numerals.

As shown in FIG. 9, a piezoelectric element 24B includes a first electrode layer 241B, a piezoelectric layer 242B, and a second electrode layer 243B. Such a piezoelectric element 24B has the same configuration as the piezoelectric elements 22 and 23 except that it is formed close to the lower surface of the vibrating arm. That is, the piezoelectric element 24B has a configuration in which the first electrode layer 241B, the piezoelectric layer 242B, and the second electrode layer 243B are stacked in that order on the lower surface 302 of the vibrating arm 30.

In the present embodiment described above, since the piezoelectric element 24 formed on the vibrating arm 30 does not have a portion positioned close to the upper surface 301 of the vibrating arm 30, it is possible to suppress the shift in the Z-axis direction of the centers of all of the vibrating arms 28, 29, and 30 more effectively than the first embodiment described above, for example.

Moreover, the third embodiment as described above can exhibit the same advantageous effects as the first embodiment described above.

The vibrator elements of the respective embodiments described hereinabove can be applied to various types of electronic devices, and the electronic devices have high reliability.

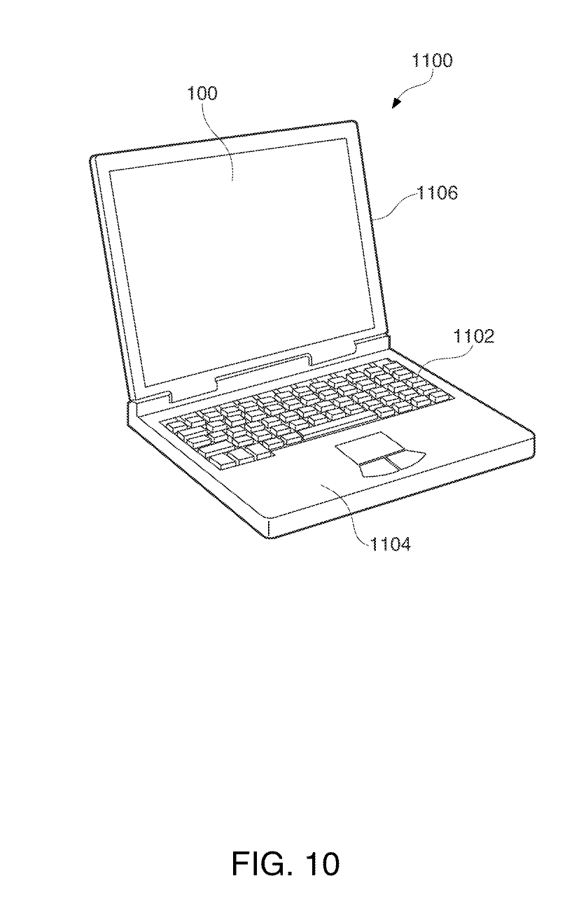

Next, an electronic device including the vibrator element according to the invention will be described in detail based on FIGS. 10 to 12.

FIG. 10 is a perspective view showing the configuration of a mobile (or notebook)-type personal computer to which an electronic device including the vibrator element according to the invention is applied. In FIG. 10, a personal computer 1100 includes a body portion 1104 including a keyboard 1102, a display unit 1106 including a display portion 100. The display unit 1106 is supported by a hinge structure so as to be pivotable about the body portion 1104.

A filter, a resonator, and the vibrator 1 functioning as a reference clock or the like are incorporated in such a personal computer 1100.

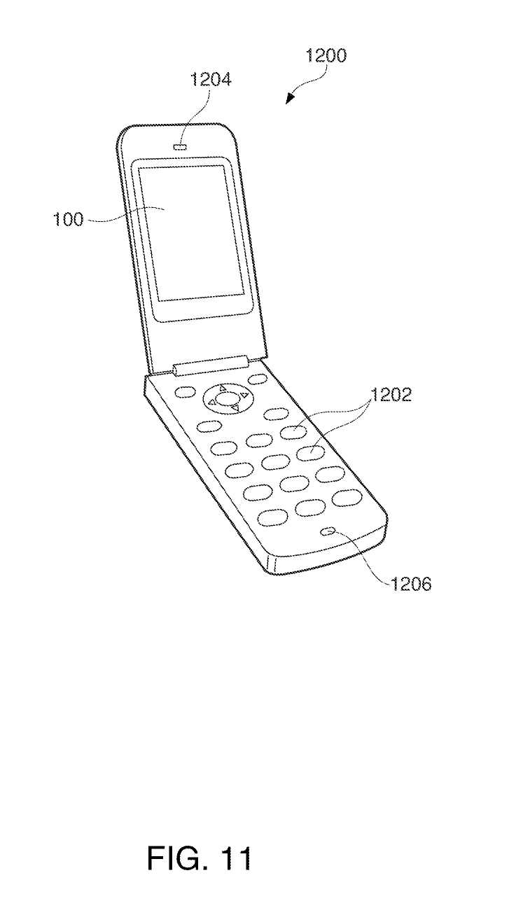

FIG. 11 is a perspective view showing the configuration of a cellular phone (including PHS) to which an electronic device including the vibrator element according to the invention is applied. In FIG. 11, a cellular phone 1200 includes a plurality of operation buttons 1202, an ear piece 1204, and a mouth piece 1206, and a display portion 100 is disposed between the operation buttons 1202 and the ear piece 1204.

A filter and the vibrator 1 functioning as a resonator or the like are incorporated in such a cellular phone 1200.

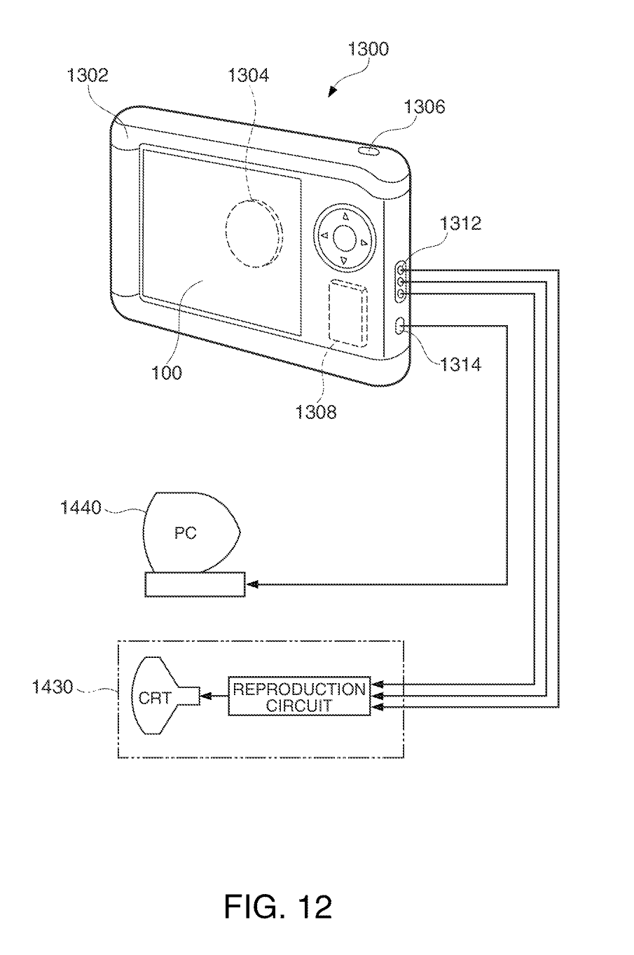

FIG. 12 is a perspective view showing the configuration of a digital still camera to which an electronic device including the vibrator element according to the invention is applied. In FIG. 12, connection to external devices is depicted in a simplified manner.

Here, general cameras expose a silver halide photographic film by a subject light image, whereas a digital still camera 1300 photoelectrically converts a subject light image using an imaging element such as a CCD (Charge Coupled Device) to generate an imaged signal (image signal).

In the digital still camera 1300, a display portion is formed on the back surface of a case (body) 1302, and an image is displayed based on the imaged signal obtained by the CCD. The display portion functions as a finder that displays a subject as an electronic image.

Moreover, a light receiving unit 1304 including an optical lens (imaging optical system), a CCD, and the like is formed on the front surface side (the rear surface side in the drawing) of the case 1302.

When a photographer presses a shutter button 1306 while monitoring a subject image displayed on the display portion, the imaged signal obtained by the CCD at that point of time is transferred and stored in a memory 1308.

Moreover, in the digital still camera 1300, a video signal output terminal 1312 and a data communication input/output terminal 1314 are formed on the side surface of the case 1302. Moreover, as shown in the drawing, a television monitor 1430 and a personal computer 1440 are connected to the video signal output terminal 1312 and the data communication input/output terminal 1314, respectively, as necessary. Furthermore, the imaged signals stored in the memory 1308 are output to the television monitor 1430 or the personal computer 1440 in accordance with a predetermined operation.

In such a digital still camera 1300, a filter and the vibrator 1 functioning as a resonator or the like are incorporated.

The electronic device including the vibrator element according to the invention can be applied to other devices other than personal computer (mobile-type personal computer), the cellular phone, and the digital still camera shown in FIGS. 10, 11, and 12, respectively. Examples of such devices include an ink jet ejection apparatus (for example, an ink jet printer), a laptop personal computer, a television, a video camera, a video tape recorder, a car navigation apparatus, a pager, an electronic pocket book (including one with communication capability), an electronic dictionary, a calculator, an electronic game machine, a word processor, a work station, a television phone, a surveillance TV monitor, electronic binoculars, a POS terminal, a medical device (for example, an electronic thermometer, a sphygmomanometer, a glucose meter, an electrocardiogram measuring system, an ultrasonic diagnosis device, and an electronic endoscope), a fish finder, various measurement instruments, various indicators (for example, indicators used in vehicles, airplanes, and ships), a flight simulator, and the like.

While the vibrator element, the vibrator, the vibration device, and the electronic device according to the invention have been described based on the embodiments, the invention is not limited to the embodiments. The configuration of the respective portions, units, and sections can be replaced with any configuration having the same function. Moreover, any two or more configurations (features) among the respective embodiments may be combined with each other to implement the invention. Furthermore, in the above embodiments, although an example in which the reinforcing member is irradiated with energy rays to perform frequency adjustment has been described, the invention is not limited to this, and the mass of the reinforcing member may be decreased by ion-etching, sand blast, or wet-etching.

For example, although in the embodiments described above, a case where the vibrator element has three vibrating arms has been described as an example, the number of vibrating arms may be two and may be four or more.

Moreover, although in the embodiments described above, a case where the piezoelectric layer and the second electrode layer of the piezoelectric element formed on the second vibrating arm have an annular shape has been described, the invention is not limited to this. For example, the piezoelectric layer and the second electrode layer may not be formed on one of both side surfaces of the second vibrating arm.

Moreover, by connecting the vibrator element to an oscillation circuit, the vibration device of the invention can be applied to a gyro sensor or the like, in addition to a piezoelectric oscillator such as a quartz crystal oscillator (SPXO), a voltage-controlled crystal oscillator (VCXO), a temperature-compensated crystal oscillator (TCXO), or an oven-controlled crystal oscillator (OCXO).

The entire disclosure of Japanese Patent Application No. 2010-200800, filed Sep. 8, 2010 is expressly incorporated by reference herein.

What is claimed is:

1. A vibrator element comprising:
a base portion formed on a plane including a first direction and a second direction orthogonal to the first direction;
a plurality of vibrating arms which extends in the first direction from the base portion and is arranged in a line in the second direction; and
a piezoelectric element which is formed in each of the vibrating arms so as to cause the vibrating arm to perform flexural vibration in a normal direction to the plane,
wherein each of the vibrating arms includes a first surface which is compressed or expanded in response to the flexural vibration, a second surface which is expanded when the first surface is compressed and which is compressed when the first surface is expanded, and a side surface that connects the first and second surfaces,
wherein a plurality of the vibrating arms includes a first vibrating arm and a second vibrating arm which perform the flexural vibration in the opposite directions to each other,
wherein the first vibrating arm has the piezoelectric element which is formed close to the first surface, and
wherein the second vibrating arm has the piezoelectric element which is formed close to the second surface.

2. The vibrator element according to claim 1,
wherein the first vibrating arm and the second vibrating arm are alternately arranged in the second direction.

3. The vibrator element according to claim 1,
wherein each of the piezoelectric elements includes a first electrode layer, a second electrode layer, and a piezoelectric layer disposed between the first and second electrode layers,
wherein the first vibrating arm disposes the first electrode layer which is formed on the first surface, and
wherein the second vibrating arm disposes the first electrode layer which is formed on the second surface.

4. The vibrator element according to claim 3,
wherein the second electrode layer which is formed in at least one of the first and second vibrating arms is extracted to a surface on the opposite side to a surface where the first electrode layer is formed through the side surface of the vibrating arm.

5. The vibrator element according to claim 1,
wherein a first connection electrode and a second connection electrode are formed on the base portion,
wherein the first connection electrode is connected to each of the first electrode layers formed on the plurality of the vibrating arms, and
wherein the second connection electrode is connected to each of the second electrode layers formed on the plurality of the vibrating arms.

6. The vibrator element according to claim 5,
wherein the piezoelectric layer is formed at least up to a formation region of the second connection electrode and overlaps with the second connection electrode in a plan view thereof.

7. A vibrator comprising:
the vibrator element according to claim 1; and
a package in which the vibrator element is accommodated.

8. A vibration device comprising:
the vibrator element according to claim 1; and
an oscillation circuit connected to the vibrator element.

9. An electronic device comprising the vibrator element according to claim 1.
